(19) United States
(12) Patent Application Publication
(10) Pub. No.: US 2014/0144375 A1
(43) Pub. Date: May 29, 2014

(54) EQUIPMENT FOR MANUFACTURING SEMICONDUCTOR

(71) Applicants: Young Dae Kim, Gyeonggi-do (KR); Jun Jin Hyon, Gyeonggi-do (KR); Sang Ho Woo, Gyeonggi-do (KR); Seung Woo Shin, Gyeonggi-do (KR)

(72) Inventors: Young Dae Kim, Gyeonggi-do (KR); Jun Jin Hyon, Gyeonggi-do (KR); Sang Ho Woo, Gyeonggi-do (KR); Seung Woo Shin, Gyeonggi-do (KR)

(73) Assignee: EUGENE TECHNOLOGY CO., LTD., Gyeonggi-do (KR)

(21) Appl. No.: 14/235,322

(22) PCT Filed: Jul. 31, 2012
(86) PCT No.: PCT/KR2012/006106

§ 371 Date: Jan. 27, 2014

(30) Foreign Application Priority Data
Aug. 2, 2011 (KR) 10-2011-0077101

(51) Int. Cl. H01L 21/67

(52) U.S. Cl. CPC H01L 21/67017
USPC 118/72

(57) ABSTRACT

Provided is an equipment for manufacturing a semiconductor. The equipment for manufacturing a semiconductor includes a cleaning chamber in which a cleaning process is performed on substrates, an epitaxial chamber in which an epitaxial process for forming an epitaxial layer on each of the substrates is performed, and a transfer chamber to which the cleaning chamber and the epitaxial chamber are connected to sides surfaces thereof, the transfer chamber including a substrate handler for transferring the substrates, on which the cleaning process is completed, into the epitaxial chamber. The cleaning chamber includes a reaction chamber connected to a side surface of the transfer chamber to perform a reaction process on the substrates and a heating chamber connected to a side surface of the transfer chamber to perform a heating process on the substrates. The reaction chamber and the heating chamber are vertically stacked on each other.

### CROSS-REFERENCE TO RELATED APPLICATIONS

This U.S. non-provisional patent application claims priority under 35 U.S.C. §119 of Korean Patent Application No. 10-2011-0077101, filed on Aug. 2, 2011, the entire contents of which is hereby incorporated by reference.

### BACKGROUND OF THE INVENTION

The present invention disclosed herein relates to an equipment for manufacturing a semiconductor, and more particularly, to an equipment for manufacturing a semiconductor which performs an epitaxial process for forming an epitaxial layer on a substrate.

Typical selective epitaxy processes involve deposition and etching reactions. The deposition and etching reactions may occur simultaneously at slightly different reaction rates with respect to a polycrystalline layer and an epitaxial layer. While an existing polycrystalline layer and/or an amorphous layer are/is deposited on at least one second layer during the deposition process, the epitaxial layer is formed on a single crystal surface. However, the deposited polycrystalline layer is etched faster than the epitaxial layer. Thus, corrosive gas may be changed in concentration to perform a net selective process, thereby realizing the deposition of an epitaxial material and the deposition of a limited or unlimited polycrystalline material. For example, a selective epitaxy process may be performed to form an epitaxial layer formed of a material containing silicon on a surface of single crystal silicon without leaving the deposits on a spacer.

Generally, the selective epitaxy process has several limitations. To maintain selectivity during the selective epitaxy process, a chemical concentration and reaction temperature of a precursor should be adjusted and controlled over the deposition process. If an insufficient silicon precursor is supplied, the etching reaction is activated to decrease the whole process rate. Also, features of the substrate may be deteriorated with respect to the etching. If an insufficient corrosive solution precursor is supplied, selectivity for forming the single crystalline and polycrystalline materials over the surface of the substrate may be reduced in the deposition reaction. Also, typical selective epitaxy processes are performed at a high reaction temperature of about 80° C., about 1,000° C., or more. Here, the high temperature is unsuited for the manufacturing process due to uncontrolled nitridation reaction and thermal budge on the surface of the substrate.

### SUMMARY OF THE INVENTION

The present invention provides an equipment for manufacturing a semiconductor which can form an epitaxial layer on a substrate.

The present invention also provides an equipment for manufacturing a semiconductor which can remove a native oxide formed on a substrate and prevent the native oxide from being formed on the substrate.

Further another object of the present invention will become evident with reference to following detailed descriptions and accompanying drawings.

Embodiments of the present invention provide equipments for manufacturing a semiconductor including: a cleaning chamber in which a cleaning process is performed on substrates; an epitaxial chamber in which an epitaxial process for forming an epitaxial layer on each of the substrates is performed; and a transfer chamber to which the cleaning chamber and the epitaxial chamber are connected to sides surfaces thereof, the transfer chamber including a substrate handler for transferring the substrates, on which the cleaning process is completed, into the epitaxial chamber, wherein the cleaning chamber may include: a reaction chamber connected to a side surface of the transfer chamber to perform a reaction process on the substrates; and a heating chamber connected to a side surface of the transfer chamber to perform a heating process on the substrates, wherein the reaction chamber and the heating chamber are vertically stacked on each other.

In some embodiments, the transfer chamber may include first and second transfer passages through which the substrates are entered into the cleaning chamber, the reaction chamber may include a reaction passage through which the substrates are entered, the heating chamber may include a heating passage through which the substrates are entered, and the equipments may further include a reaction-side gate valve for separating the reaction chamber from the transfer chamber and a heating-side gate valve for separating the heating chamber from the transfer chamber.

In other embodiments, the reaction chamber may include: a radical supply line connected to the reaction chamber to supply radicals; and a gas supply line connected to the reaction chamber to supply a reaction gas.

In still other embodiments, the reaction chamber may further include a susceptor on which the substrates are placed, the susceptor rotating the substrates during the reaction process.

In even other embodiments, the reaction gas may include a fluoride gas including nitrogen fluoride (NF3).

In yet other embodiments, the heating chamber may include: a susceptor on which the substrates are placed; and a heater heating the substrates placed on the susceptor.

In further embodiments, the equipments may further include a buffer chamber connected to a side surface of the transfer chamber, the buffer chamber including a storage space for stacking the substrates; wherein the substrate handler may successively stack the substrates, on which the cleaning process is completed, into the storage space, transfer the stacked substrates into the epitaxial chamber, and successively stack the substrates, on which the epitaxial layers are respectively formed, into the storage space.

In still further embodiments, the loading space may include a first loading space in which the substrates, on which the cleaning process is completed, are loaded and a second loading space in which the substrates, on which the epitaxial layers are respectively formed, are loaded.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic view of an equipment for manufacturing a semiconductor according to an embodiment of the present invention;

FIG. 2 is a view illustrating a substrate treated according to an embodiment of the present invention;

FIG. 3 is a flowchart illustrating a process for forming an epitaxial layer according to an embodiment of the present invention;

FIG. 4 is a view of a buffer chamber of FIG. 1;

FIG. 5 is a view of a substrate holder of FIG. 4;

FIG. 6 is a view of a cleaning chamber of FIG. 1;

FIG. 7 is a view illustrating a modified example of the cleaning chamber of FIG. 1;

FIG. 8 is a view of an epitaxial chamber of FIG. 1; and

FIG. 9 is a view of a supply tube of FIG. 1.

### DETAILED DESCRIPTION OF PREFERRED EMBODIMENTS

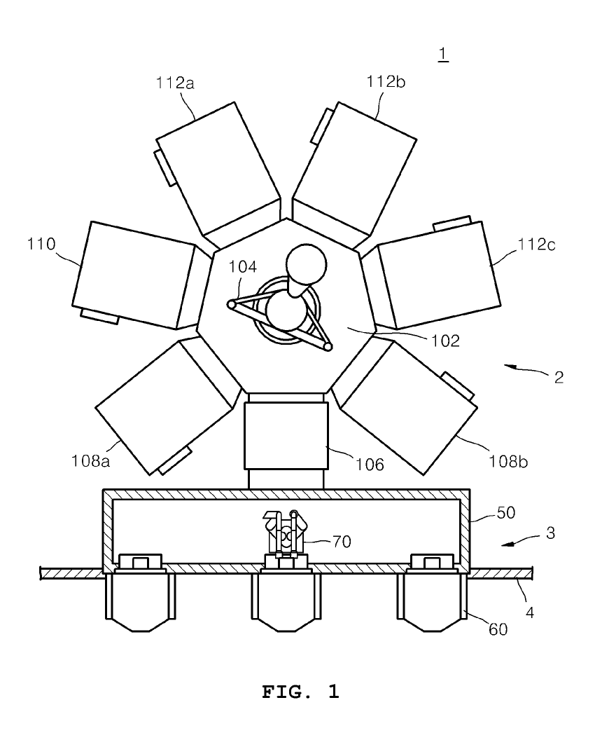

Hereinafter, exemplary embodiments of the present invention will be described in detail with reference to FIGS. 1 to 9. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

FIG. 1 is a schematic view of an equipment 1 for manufacturing a semiconductor according to an embodiment of the present invention. The equipment 1 for manufacturing the semiconductor includes a process equipment 2, an equipment front end module (EFEM) 3, and an interface wall 4. The EFEM 3 is mounted on a front side of the process equipment 2 to transfer a wafer W between a container (not shown) in which substrates S are received and the process equipment 2.

The EFEM 3 includes a plurality of loadports 60 and a frame 50. The frame 50 is disposed between the loadports 60 and the process equipment 2. The container in which the substrates S are received is placed on each of the loadports 60 by a transfer unit (not shown) such as an overhead transfer, an overhead conveyor, or an automatic guided vehicle.

An airtight container such as a front open unified pod (FOUP) may be used as the container. A frame robot 70 for transferring the substrates S between the container placed on each of the loadports 60 and the process equipment 2 is disposed within the frame 50. A door opener (not shown) for automatically opening or closing a door of the container may be disposed within the frame 50. Also, a fan filter unit (FFU) (not shown) for supplying clean air into the frame 50 may be provided within the frame 50 so that the clean air flows downward from an upper side within the frame 50.

Predetermined processes with respect to the substrates S are performed within the process equipment 2. The process equipment 2 includes a transfer chamber 102, a loadlock chamber 106, cleaning chambers 108a and 108b, a buffer chamber 110, and epitaxial chambers 112a, 112b, and 112c. The transfer chamber 102 may have a substantially polygonal shape when viewed from an upper side. The loadlock chamber 106, the cleaning chambers 108a and 108b, the buffer chamber 110, and the epitaxial chambers 112a, 112b, and 112c are disposed on side surfaces of the transfer chamber 102, respectively.

The loadlock chamber 106 is disposed on a side surface adjacent to the EFEM 3 among the side surfaces of the transfer chamber 102. The substrate S is loaded to the process equipment 2 after the substrate S is temporarily stayed within the loadlock chamber 106 so as to perform the processes. After the processes are completed, the substrate S is unloaded from the process equipment 2 and then is temporarily stayed within the loadlock chamber 106. The transfer chamber 102, the cleaning chambers 108a and 108b, the buffer chamber 110, and the epitaxial chambers 112a, 112b, and 112c are maintained in a vacuum state. The loadlock chamber 106 is converted from the vacuum state to an atmospheric state. The loadlock chamber 106 prevents external contaminants from being introduced into the transfer chamber 102, the cleaning chambers 108a and 108b, the buffer chamber 110, and the epitaxial chambers 112a, 112b, and 112c. Also, since the substrate S is not exposed to the atmosphere during the transfer of the substrate S, it may prevent an oxide from being grown on the substrate S.

Gate valves (not shown) are disposed between the loadlock chamber 106 and the transfer chamber 102 and between the loadlock chamber 106 and the EFEM 3, respectively. When the substrate S is transferred between the EFEM 3 and the loadlock chamber 106, the gate valve disposed between the loadlock chamber 106 and the transfer chamber 102 is closed. When the substrate S is transferred between the loadlock chamber 106 and the transfer chamber 102, the gate valve disposed between the loadlock chamber 106 and the EFEM 3 is closed.

A substrate handler 104 is provided in the transfer chamber 102. The substrate handler 104 transfers the substrate S between the loadlock chamber 106, the cleaning chamber 108a and 108b, the buffer chamber 110, and the epitaxial chambers 112a, 112b, and 112c. The transfer chamber 102 is sealed so that the transfer chamber 102 is maintained in the vacuum state when the substrate S is transferred. The maintenance of the vacuum state is for preventing the substrate S from being exposed to contaminants (e.g., O₂, particle materials, and the like).

The epitaxial chambers 112a, 112b, and 112c are provided to form an epitaxial layer on the substrate S. In the current embodiment, three epitaxial chambers 112a, 112b, and 112c are provided. Since it takes a relatively long time to perform an epitaxial process when compared to that of a cleaning process, the plurality of epitaxial chambers may be provided to improve manufacturing yield. Unlike the current embodiment, four or more epitaxial chambers or two or less epitaxial chambers may be provided.

The cleaning chambers 108a and 108b is configured to clean the substrate S before the epitaxial process is performed on the substrate S within the epitaxial chambers 112a, 112b, and 112c. To successively perform the epitaxial process, an amount of oxide remaining on the crystalline substrate should be minimized. If an oxygen content on a surface of the substrate S is too high, oxygen atoms interrupts crystallographic disposition of materials to be deposited on a seed substrate. Thus, it may have a bad influence on the epitaxial process. For example, when a silicon epitaxial deposition is performed, excessive oxygen on the crystalline substrate may displace silicon atoms from its epitaxial position by oxygen atom clusters in atom units. The local atom displacement may cause errors in follow-up atom arrangement when a layer is more thickly grown. This phenomenon may be so-called stacking faults or hillock defects. The oxygenation on the surface of the substrate S may, for example, occur when the substrate is exposed to the atmosphere while the substrate is transferred. Thus, the cleaning process for removing a native oxide (or surface oxide) formed on the substrate S may be performed within the cleaning chambers 108a and 108b.

The cleaning process may be a dry etching process using hydrogen (H*) and NF₃ gases having a radical state. For example, when the silicon oxide formed on the surface of the substrate is etched, the substrate is disposed within a chamber, and then a vacuum atmosphere is formed within the chamber to generate an intermediate product reacting with the silicon oxide within the chamber.

For example, when radicals (H*) of a hydrogen gas and a reaction gas such as a fluoride gas (for example, nitrogen fluoride (NF₃)) are supplied into the chamber, the reaction gases are reduced as expressed in following reaction formula (1) to generate an intermediate product such as NHₓF_{y} (where x and y are certain integers).

H*+NF₃ [symbol] NHₓF_{y} (1)

Since the intermediate product has high reactivity with silicon oxide (SiO₂), when the intermediate product reaches a surface of the silicon substrate, the intermediate product selectively reacts with the silicon oxide to generate a reaction product ((NH₄)₂SiF₆) as expressed in following reaction formula (2).

NHₓF_{y}+SiO₂ [symbol] (NH₄)₂SiF₆+H₂O (2)

Thereafter, when the silicon substrate is heated as a temperature of about 100° C. or more, the reaction product is pyrolyzed as expressed in following reaction formula (3) to form a pyrolysis gas, and then the pyrolysis gas is evaporated. As a result, the silicon oxide may be removed from the surface of the substrate. As shown in the following reaction formula (3), the pyrolysis gas includes a gas containing fluorine such as an HF gas or a SiF₄ gas.

(NH₄)₂SiF₆ [symbol] NH₃+HF+SiF₄ (3)

As described above, the cleaning process may include a reaction process for generating the reaction product and a heating process for pyrolyzing the reaction product. The reaction process and the heating process may be performed at the same time within the cleaning chambers 108a and 108b. Alternatively, the reaction process may be performed within one of the cleaning chambers 108a and 108b, and the heating process may be performed within the other one of the cleaning chambers 108a and 108b.

The buffer chamber 110 provides a space in which the substrate S, on which the cleaning process is completed, is loaded and a space in which the substrate S, on which the epitaxial process is performed, is loaded. When the cleaning process is completed, the substrate S is transferred into the buffer chamber 110 and then loaded within the buffer chamber 110 before the substrate is transferred into the epitaxial chambers 112a, 112b, and 112c. The epitaxial chambers 112a, 112b, and 112c may be batch type chambers in which a single process is performed on a plurality of substrates. When the epitaxial process is completed within the epitaxial chambers 112a, 112b, and 112c, substrates S on which the epitaxial process is performed are successively loaded within the buffer chamber 110. Also, substrates S on which the cleaning process is completed are successively loaded within the epitaxial chambers 112a, 112b, and 112c. Here, the substrates S may be vertically loaded within the buffer chamber 110.

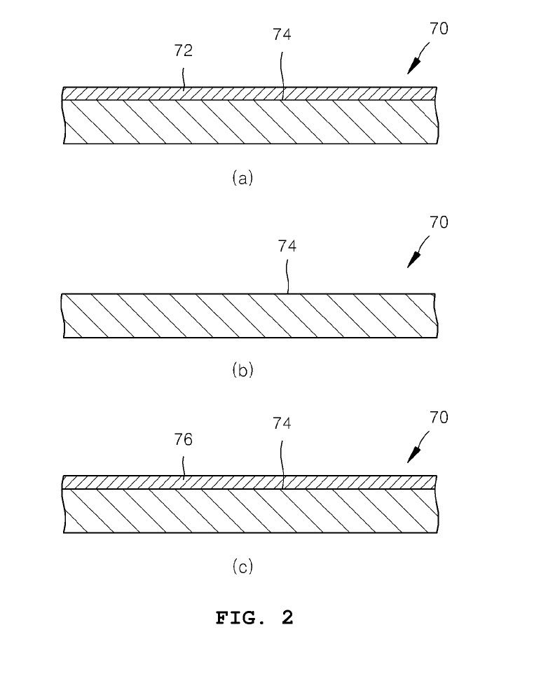

FIG. 2 is a view illustrating a substrate treated according to the embodiment of the present invention. As described above, the cleaning process is performed on the substrate S within the cleaning chambers 108a and 108b before the epitaxial process is performed on the substrate S. Thus, an oxide 72 formed on a surface of a substrate 70 may be removed through the cleaning process. The oxide 72 may be removed through the cleaning process within the cleaning chamber 108a and 108b. Also, an epitaxy surface 74 formed on the surface of the substrate 70 may be exposed through the cleaning process to assist the growth of an epitaxial layer.

Thereafter, an epitaxial process is performed on the substrate 70 within the epitaxial chambers 112a, 112b, and 112c. The epitaxial process may be performed by chemical vapor deposition. The epitaxial process may be performed to form an epitaxial layer 76 on the epitaxy surface 74. The epitaxy surface 74 formed on the substrate 70 may be exposed by reaction gases including a silicon gas (e.g., SiCl₄, SiHCl₃, SiH₂Cl₂, SiH₃Cl, Si₂H₆, or SiH₄) and a carrier gas (e.g., N₂ and/or H₂). Also, when the epitaxial layer 76 is required to include a dopant, a silicon-containing gas may include a dopant-containing gas (e.g., AsH₃, PH3, and/or B₂H₆),

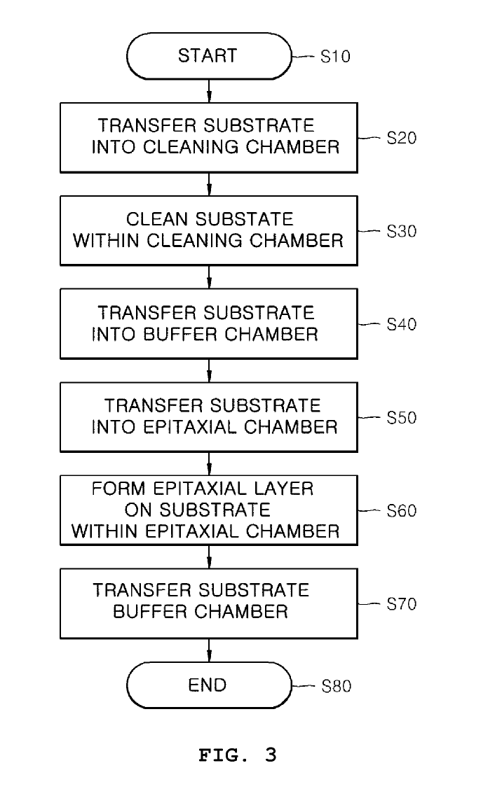

FIG. 3 is a flowchart illustrating a process for forming an epitaxial layer according to an embodiment of the present invention. In operation S10, a process for forming an epitaxial layer starts. In operation S20, a substrate S is transferred into cleaning chambers 108a and 108b before an epitaxial process is performed on the substrate S. Here, a substrate handler 104 transfers the substrate S into the cleaning chambers 108a and 108b. The transfer of the substrate S is performed through a transfer chamber 102 in which a vacuum state is maintained. In operation S30, a cleaning process is performed on the substrate S. As described above, the cleaning process includes a reaction process for generating a reaction product and a heating process for pyrolyzing the reaction product. The reaction process and the heating process may be performed at the same time within the cleaning chambers 108a and 108b. Alternatively, the reaction process may be performed within one of the cleaning chambers 108a and 108b, and the heating process may be performed within the other one of the cleaning chambers 108a and 108b.

In operation S40, the substrate S on which the cleaning process is completed is transferred into a buffer chamber 110 and is stacked within the buffer chamber 110. Then, the substrate S is on standby within the buffer chamber 110 so as to perform the epitaxial process. In operation S50, the substrate S is transferred into epitaxial chambers 112a, 112b, and 112c. The transfer of the substrate S is performed through the transfer chamber 102 in which the vacuum state is maintained. In operation S60, an epitaxial layer may be formed on the substrate S. In operation S70, the substrate S is transferred again into the buffer chamber 110 and is stacked within the buffer chamber 110. Thereafter, in operation S80, the process for forming the epitaxial layer is ended.

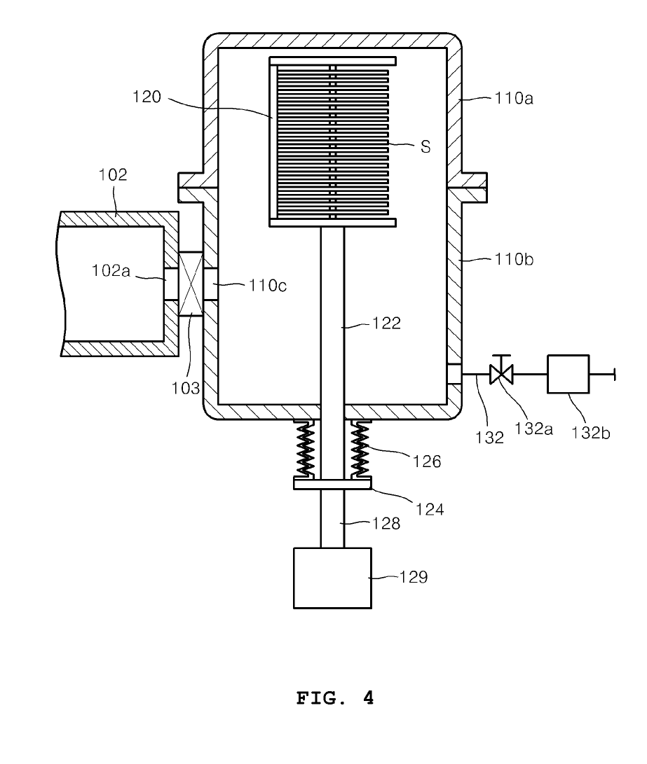

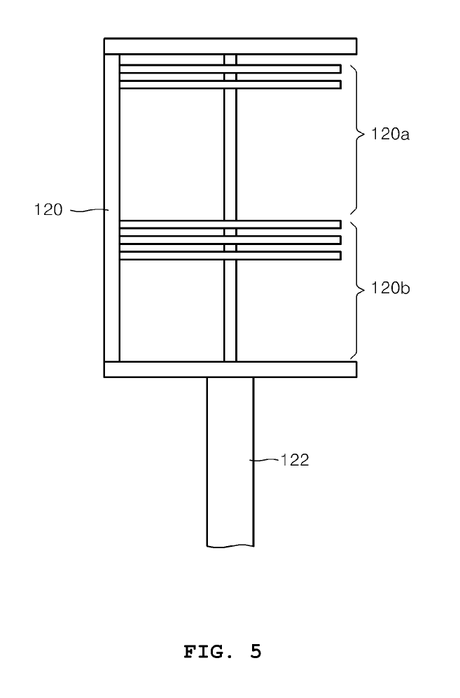

FIG. 4 is a view of the buffer chamber of FIG. 1. FIG. 5 is a view of a substrate holder of FIG. 4. The buffer chamber 110 includes an upper chamber 110a and a lower chamber 110b. The lower chamber 110b has a passage 110c defined in a side corresponding to the transfer chamber 102. A substrate S is loaded from the transfer chamber 102 to the buffer chamber 110 through the passage 110c. The transfer chamber 102 has a buffer passage 102a defined in a side corresponding to the buffer chamber 110. A gate valve 103 is disposed between the buffer passage 102a and the passage 110c. The gate valve 103 may separate the transfer chamber 102 and the buffer chamber 110 from each other. The buffer passage 102a and the passage 110c may be opened or closed by the gate valve 103.

The buffer chamber 110 includes a substrate holder 120 on which substrates S are stacked. Here, the substrates S are vertically stacked on the substrate holder 120. The substrate holder 120 is connected to an ascending/descending shaft 122. The ascending/descending shaft 122 passes through the lower chamber 110b and is connected to a support plate 124 and a driving shaft 128. The driving shaft 128 ascends or descends by an elevator 129. The ascending/descending shaft 122 and the substrate holder 120 may ascend or descend by the driving shaft 128.

The substrate handler 104 successively transfers the substrates S, on which the cleaning process is completed, into the buffer chamber 110. Here, the substrate holder 120 ascends or descends by the elevator 129. As a result, an empty slot of the substrate holder 120 is moved at a position corresponding to the passage 110c. Thus, the substrates S transferred into the buffer chamber 110 are stacked on the substrate holder 120. Here, the substrate holder 120 may ascend or descend to vertically stack the substrates S.

Referring to FIG. 5, the substrate holder 120 has an upper storage space 120a and a lower storage space 120b. As described above, the substrates S on which the cleaning process is completed and the substrates S on which the epitaxial process is completed are stacked on the substrate holder 120. Thus, it may be necessary to separate the substrates S on which the cleaning process is completed and the substrates S on which the epitaxial process is completed from each other. That is, the substrates S, on which the cleaning process is completed, are stacked within the upper storage space 120a, and the substrates S, on which the epitaxial process is completed, are stacked within the lower storage space 120b. For example, thirteen substrates S may be stacked within the upper storage space 120a. That is, the thirteen substrates S may be treated within one epitaxial chamber 112a, 112b, or 112c. Similarly, thirteen substrates S may be stacked within the lower storage space 120b.

The lower chamber 110b is connected to an exhaust line 132. The inside of the buffer chamber 110 may be maintained in a vacuum state through an exhaust pump 132b. A valve 132a opens or closes the exhaust line 132. A bellows 126 connects a lower portion of the lower chamber 110b to the support plate 124. The inside of the buffer chamber 110 may be sealed by the bellows 126. That is, the bellows 126 prevents the vacuum state from being released through a circumference of the ascending/descending shaft 122.

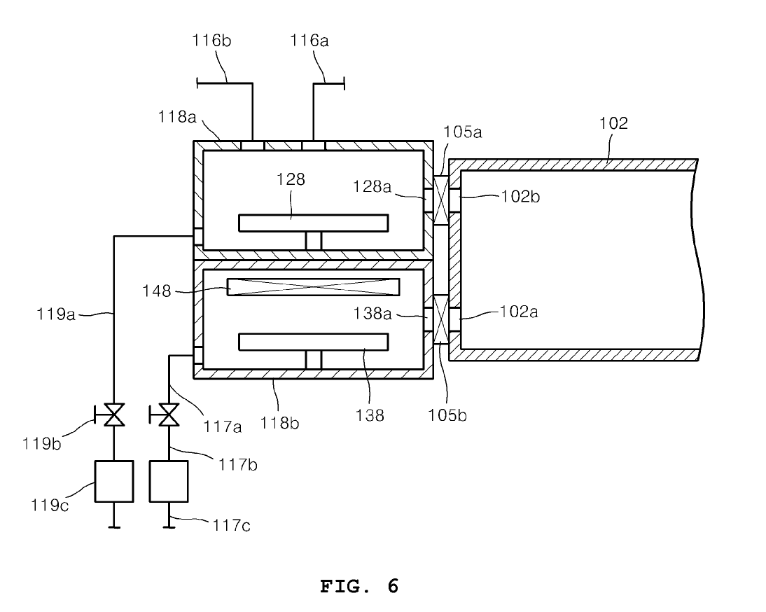

FIG. 6 is a view of the cleaning chamber of FIG. 1. As described above, the cleaning chambers 108a and 108b may be chambers in which the same process is performed. Thus, only the cleaning chamber 108a will be exemplified below.

The cleaning chamber 108a includes an upper chamber 118a and a lower chamber 118b. The upper chamber 118a and the lower chamber 118b may be vertically stacked on each other. The upper chamber 118a and the lower chamber 118b have an upper passage 128a and a lower passage 138a which are defined in a side corresponding to the transfer chamber 102, respectively. The substrates S may be loaded to the upper chamber 118a and the lower chamber 118b through the upper passage 128a and the lower passage 138a, respectively. The transfer chamber 102 has an upper passage 102b and a lower passage 102a defined in sides respectively corresponding to the upper chamber 118a and the lower chamber 118b. An upper gate valve 105a is disposed between the upper passage 102b and the upper passage 128a, and a lower gate valve 105b is disposed between the lower passage 102a and the lower passage 138a. The gate valves 105a and 105b separates the upper chamber 118a and the transfer chamber 102, and the lower chamber 118b and the transfer chamber 102 from each other, respectively. The upper passage 102b and the upper passage 128a may be opened and closed through the upper gate valve 105a. Also, the lower passage 102a and the lower passage 138a may be opened and closed through the lower gate valve 105b.

A reaction process using radicals may be performed on the substrates S in the upper chamber 118a. The upper chamber 118a is connected to a radical supply line 116a and a gas supply line 116b. The radical supply line 116a is connected to a gas container (not shown) in which a radical generation gas (e.g., H₂ or NH₃) is filled and a gas container (now shown) in which a carrier gas (N₂) is filled. When a valve of each of the gas containers is opened, the radical generation gas and the carrier gas are supplied into the upper chamber 118a. Also, the radical supply line 116a is connected to a microwave source (not shown) through a wave guide. When the microwave source generates microwaves, the microwaves proceed into the wave guide and then are introduced into the radical supply line 116a. In this state, when the radical generation gas flows, the radical generation gas is plasmarized by the microwaves to generate radicals. The generated radicals together with the non-treated radical generation gas, the carrier gas, and byproducts due to the plasmarization may flow along the radical supply line 116a and be introduced into the upper chamber 118a. Unlike the current embodiment, the radicals may be generated by ICP type remote plasma. That is, when the radical generation gas is supplied into the ICP type remote plasma source, the radical generation gas is plasmarized to generate radicals. The generated radicals may flow along the radial supply line 116a and be introduced into the upper chamber 118a.

The radicals (e.g., hydrogen radicals) are supplied into the upper chamber 118a through the radical supply line 116a, and the reaction gas (e.g., a fluoride gas such as nitrogen fluoride (NF₃)) is supplied into the upper chamber 118a through the gas supply line 116b. Then, the radicals and the reaction gas are mixed to react with each other. In this case, reaction formula may be expressed as follows.

H*+NF₃ [symbol] NHₓF_{y}(NH₄FH,NH₄FHF,etc)

NHₓF_{y}+SiO₂ [symbol] (NH₄F)SiF₆+H₂O↑

That is, the reaction gas previously absorbed onto a surface of the substrate S and the radicals react with each other to generate an intermediate product (NHₓF_{y}). Then, the intermediate product (NHₓF_{y}) and native oxide (SiO₂) formed on the surface of the substrate S react with each other to generate a reaction product ((NH₄F)SiF₆). The substrate S is placed on a susceptor 128 disposed within the upper chamber 118a. The susceptor 128 rotates the substrate S during the reaction process to assist the reaction so that the reaction uniformly occurs.

The upper chamber 118a is connected to an exhaust line 119a. Before the reaction process is performed, the inside of the upper chamber 118a may be vacuum-exhausted by an exhaust pump 119c, and also, the radicals, the reaction gas, the non-reaction radical generation gas, the byproducts due to the plasmarization, and the carrier gas within the upper chamber 118a may be exhausted to the outside. A valve 119b opens or closes the exhaust line 119a.

A heating process is performed on the substrate S within the lower chamber 118b. Thus, a heater 148 is disposed in an inner upper portion of the lower chamber 118b. When the reaction process is completed, the substrate S is transferred into the lower chamber 118b through the substrate handler 104. Here, since the substrate S is transferred through the transfer chamber 102 in which the vacuum state is maintained, it may prevent the substrate S from being exposed to contaminants (e.g., O₂, particle materials, and the like).

The heater 148 heats the substrate S at a predetermined temperature (i.e., a temperature of about 100° C. or more, for example, a temperature of about 130° C.). Thus, the reaction product may be pyrolyzed to generate a pyrolysis gas such as HF or SiF₄ which gets out of the surface of the substrate S. Then, the reaction product may be vacuum-exhausted to remove a thin film formed of silicon oxide from the surface of the substrate S. The substrate S is placed on a susceptor 138 disposed under the heater 148. The heater 148 heats the substrate S placed on the susceptor 138.

(NH₄F)₆SiF₆ [symbol] NH₃↑+HF↑+SiF₄↑

The lower chamber 118b is connected to an exhaust line 117a. Reaction byproducts (e.g., NH₃, HF, SiF₄, and the like) within the lower chamber 118b may be exhausted to the outside through an exhaust pump 117c. A valve 117b opens or closes the exhaust line 117a.

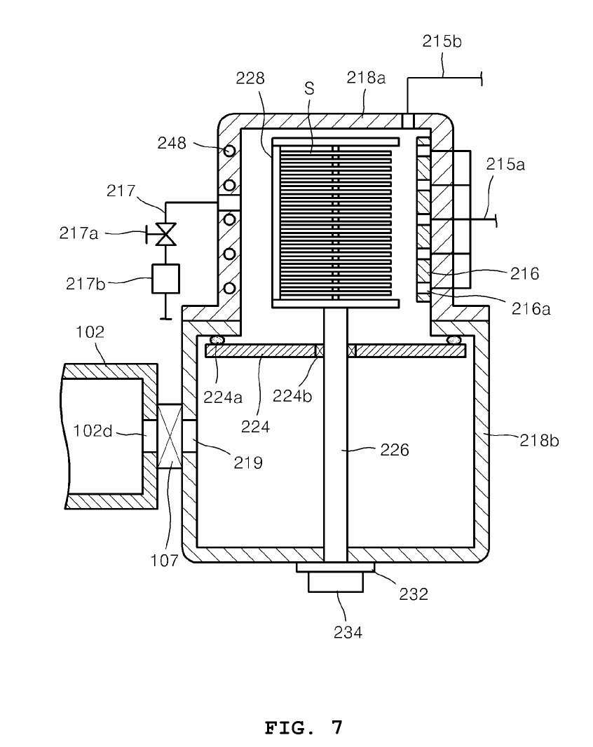

FIG. 7 is a view illustrating a modified example of the cleaning chamber of FIG. 1. A cleaning chamber 108a includes an upper chamber 218a and a lower chamber 218b. The upper chamber 218a and the lower chamber 218b communicate with each other. The lower chamber 218b has a passage 219 defined in a side corresponding to the transfer chamber 102. A substrate S may be loaded from the transfer chamber 102 to the cleaning chamber 108a through the passage 219. The transfer chamber 102 has a transfer passage 102d defined in a side corresponding to the cleaning chamber 108a. A gate valve 107 is disposed between the transfer passage 102d and the passage 219. The gate valve 107 may separate the transfer chamber 102 and the cleaning chamber 108a from each other. The transfer passage 102d and the passage 219 may be opened or closed by the gate valve 107.

The cleaning chamber 108a includes a substrate holder 228 on which substrates S are stacked. The substrates S are vertically stacked on the substrate holder 228. The substrate holder 228 is connected to a rotation shaft 226. The rotation shaft 226 passes through the lower chamber 218b and is connected to an elevator 232 and a driving motor 234. The rotation shaft 226 ascends or descends by the elevator 232. The substrate holder 228 may ascend or descend together with the rotation shaft 226. The rotation shaft 226 is rotated by the driving motor 234. While an etching process is performed, the substrate holder 228 may be rotated together with the rotation shaft 226.

The substrate handler 104 successively transfers the substrates S into the cleaning chamber 108a. Here, the substrate holder 228 ascends or descends by the elevator 232. As a result, an empty slot of the substrate holder 228 is moved at a position corresponding to the passage 219. Thus, the substrates S transferred into the cleaning chamber 108a are stacked on the substrate holder 228. Here, the substrate holder 228 may ascend or descend to vertically stack the substrates S. For example, thirteen substrates S may be stacked on the substrate holder 228.

When the substrate holder 228 is disposed within the lower chamber 218b, the substrates S are stacked within the substrate holder 228. As shown in FIG. 7, when the substrate holder 228 is disposed within the upper chamber 218a, the cleaning process is performed on the substrates S. The upper chamber 218a provides a process space in which the cleaning process is performed. A support plate 224 is disposed on the rotation shaft 226. The support plate 224 ascends together with the substrate holder 228 to block the process space within the upper chamber 218a from the outside. The support plate 224 is disposed adjacent to an upper end of the lower chamber 218b. A sealing member 224a (e.g., an O-ring, and the like) is disposed between the support plate 224 and the upper end of the lower chamber 218b to seal the process space. A bearing member 224b is disposed between the support plate 224 and the rotation shaft 226. The rotation shaft 226 may be rotated in a state where the rotation shaft 226 is supported by the bearing member 224b.

A reaction process and heating process are performed on the substrates within the process space defined in the upper chamber 218a. When all the substrates S are stacked on the substrate holder 228, the substrate holder 228 ascends by the elevator 232 and then is moved into the process space within the upper chamber 218a. An injector 216 is disposed on a side of the inside of the upper chamber 218a. The injector 216 has a plurality of injection holes 216a.

The injector 216 is connected to a radical supply line 215a. Also, the upper chamber 218a is connected to a gas supply line 215b. The radical supply line 215a is connected to a gas container (not shown) in which a radical generation gas (e.g., H₂ or NH₃) is filled and a gas container (now shown) in which a carrier gas (N₂) is filled. When a valve of each of the gas containers is opened, the radical generation gas and the carrier gas are supplied into the process space through the injector 216. Also, the radical supply line 215a is connected to a microwave source (not shown) through a wave guide. When the microwave source generates microwaves, the microwaves proceed into the wave guide and then are introduced into the radical supply line 215a. In this state, when the radical generation gas flows, the radical generation gas is plasmarized by the microwaves to generate radicals. The generated radicals together with the non-treated radical generation gas, the carrier gas, and byproducts due to the plasmarization may flow into the radical supply line 215a and be supplied into the injector 216, and then be introduced into the process space through the injector 216. Unlike the current embodiment, the radicals may be generated by ICP type remote plasma. That is, when the radical generation gas is supplied into the ICP type remote plasma source, the radical generation gas is plasmarized to generate radicals. The generated radicals may flow along the radial supply line 215a and be introduced into the upper chamber 218a.

The radicals (e.g., hydrogen radicals) are supplied into the upper chamber 218a through the radical supply line 215a, and the reaction gas (e.g., a fluoride gas such as nitrogen fluoride (NF₃)) is supplied into the upper chamber 218a through the gas supply line 215b. Then, the radicals and the reaction gas are mixed to react with each other. In this case, reaction formula may be expressed as follows.

H*+NF₃ [symbol] NHₓF_{y}(NH₄FH,NH₄FHF,etc)

NHₓF_{y}+SiO₂ [symbol] (NH₄F)SiF₆+H₂O↑

That is, the reaction gas previously absorbed onto the surface of a substrate S and the radicals react with each other to generate an intermediate product (NHₓF_{y}). Then, the intermediate product (NHₓF_{y}) and native oxide (SiO₂) formed on the surface of the substrate S react with each other to generate a reaction product ((NH⁴F)SiF₆). The substrate holder 228 rotates the substrate S during the etching process to assist the etching process so that the etching process is uniformly performed.

The upper chamber 218a is connected to an exhaust line 217. Before the reaction process is performed, the inside of the upper chamber 218a may be vacuum-exhausted by an exhaust pump 217b, and also, the radicals, the reaction gas, the non-reaction radical generation gas, the byproducts due to the plasmarization, and the carrier gas within the upper chamber 218a may be exhausted to the outside. A valve 217a opens or closes the exhaust line 217.

A heater 248 is disposed on the other side of the upper chamber 218a. The heater 248 heats the substrate S at a predetermined temperature (i.e., a temperature of about 100° C. or more, for example, a temperature of about 130° C.) after the reaction process is completed. As a result, the reaction product may be pyrolyzed to generate a pyrolysis gas such as HF or SiF4 which gets out of the surface of the substrate S. Then, the reaction product may be vacuum-exhausted to remove a thin film formed of silicon oxide from the surface of the substrate S. The reaction product (e.g., NH₃, HF, and SiF₄) may be exhausted through the exhaust line 217.

(NH₄F)₆SiF₆ [symbol] NH₃↑+HF↑+SiF₄↑

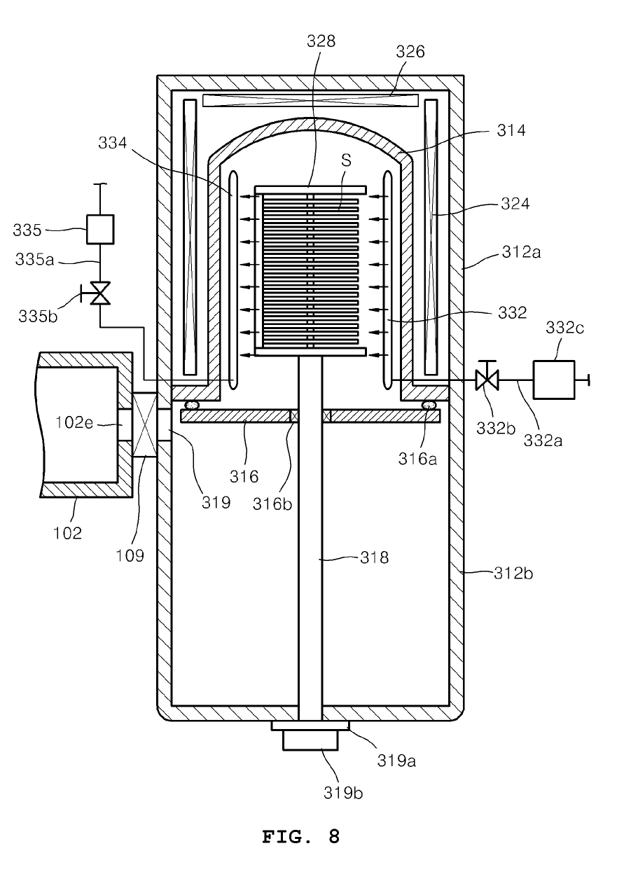

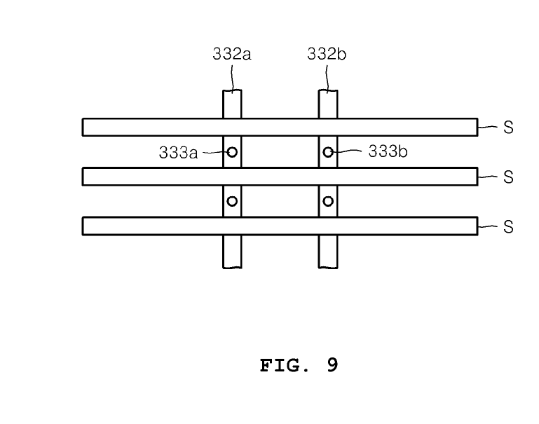

FIG. 8 is a view of the epitaxial chambers of FIG. 1, and FIG. 9 is a view of a supply tube of FIG. 1. The epitaxial chambers 112a, 112b, and 112c may be chambers in which the same process is performed. Thus, only the cleaning chamber 112a will be exemplified below.

The epitaxial chamber 112a includes an upper chamber 312a and a lower chamber 312b. The upper chamber 312a and the lower chamber 312b communicate with each other. The lower chamber 312b has a passage 319 defined in a side corresponding to the transfer chamber 102. A substrate S may be loaded from the transfer chamber 102 to the epitaxial chamber 112a through the passage 319. The transfer chamber 102 has a transfer passage 102e defined in a side corresponding to the epitaxial chamber 112a. A gate valve 109 is disposed between the transfer passage 102e and the passage 319. The gate valve 109 may separate the transfer chamber 102 and the epitaxial chamber 112a from each other. The transfer passage 102e and the passage 319 may be opened or closed by the gate valve 109.

The epitaxial chamber 112a includes a substrate holder 328 on which substrates S are stacked. The substrates S are vertically stacked on the substrate holder 328. The substrate holder 328 is connected to a rotation shaft 318. The rotation shaft 318 passes through the lower chamber 312b and is connected to an elevator 319a and a driving motor 319b. The rotation shaft 318 ascends or descends by the elevator 319a. The substrate holder 328 may ascend or descend together with the rotation shaft 318. The rotation shaft 318 is rotated by the driving motor 319b. While an epitaxial process is performed, the substrate holder 328 may be rotated together with the rotation shaft 318.

The substrate handler 104 successively transfers the substrates S into epitaxial chamber 112a. Here, the substrate holder 328 ascends or descends by the elevator 319a. As a result, an empty slot of the substrate holder 328 is moved at a position corresponding to the passage 319. Thus, the substrates S transferred into the epitaxial chamber 112a are stacked on the substrate holder 328. Here, the substrate holder 328 may ascend or descend to vertically stack the substrates S. For example, thirteen substrates S may be stacked on the substrate holder 328.

When the substrate holder 328 is disposed within the lower chamber 312b, the substrates S are stacked within the substrate holder 328. As shown in FIG. 8, when the substrate holder 328 is disposed within a reaction tube 314, the epitaxial process is performed on the substrates S. The reaction tube 314 provides a process space in which the epitaxial process is performed. A support plate 316 is disposed on the rotation shaft 318. The support plate 316 ascends together with the substrate holder 328 to block the process space within the reaction tube 314 from the outside. The support plate 316 is disposed adjacent to a lower end of the reaction tube 314. A sealing member 316a (e.g., an O-ring, and the like) is disposed between the support plate 316 and the lower end of the reaction tube 314 to seal the process space. A bearing member 316b is disposed between the support plate 316 and the rotation shaft 318. The rotation shaft 318 may be rotated in a state where the rotation shaft 318 is supported by the bearing member 316b.

The epitaxial process is performed on the substrates S within the process space defined in the reaction tube 314. A supply tube 332 is disposed on one side of the inside of the reaction tube 314. An exhaust tube 334 is disposed on the other side of the inside of the reaction tube 314. The supply tube 332 and the exhaust tube 334 may be disposed to face each other with respect to a center of the substrates S. Also, the supply tube 332 and the exhaust tube 334 may be vertically disposed according to the stacked direction of the substrates S. A lateral heater 324 and an upper heater 326 are disposed outside the reaction tube 314 to heat the process space within the reaction tube 314.

The supply tube 332 is connected to a supply line 332a, and the supply line 332a is connected to a reaction gas source 332c. The reaction gas is stored in the reaction gas source 332c and supplied into the supply tube 332 through the supply line 332a. Referring to FIG. 9, the supply tube 332 may include first and second supply tubes 332a and 332b. The first and second supply tubes 332a and 332b have a plurality of supply holes 333a and 333b spaced from each other in a length direction. Here, the supply holes 333a and 333b may have the substantially same number as that of substrates S loaded to the reaction tube 314. Also, the supply holes 333a and 333b may be defined to corresponding between the substrates S or defined regardless of positions of the substrates S. Thus, a reaction gas supplied through the supply holes 333a and 333b may smoothly flow along a surface of a substrate S to form an epitaxial layer on the substrate S in a state where the substrate S is heated. The supply line 332a may be opened or closed by a valve 332b.

The first supply tube 332a may supply a deposition gas (a silicon gas (e.g., SiCl₄, SiHCl₃, SiH₂Cl₂, SiH₃Cl, Si₂H₆, or SiH₄)) and a carrier gas (e.g., N₂ and/or H₂). The second supply tube 332b may supply an etching gas. A selective epitaxy process involves deposition reaction and etching reaction. Although not shown in the current embodiment, when the epitaxial layer is required to include a dopant, a third supply tube may be added. The third supply tube may supply a dopant-containing gas (e.g., arsine (AsH₃), phosphine (PH₃), and/or diborane (B₂H₆)).

The exhaust tube 334 may be connected to an exhaust line 335a to exhaust reaction byproducts within the reaction tube 314 to the outside through an exhaust pump 335. The exhaust tube 334 has a plurality of exhaust holes. Like the supply holes 333a and 333b, the plurality of exhaust holes may be defined to corresponding between the substrates S or defined regardless of positions of the substrates S. A valve 334b opens or closes the exhaust line 334a.

Although the present invention is described in more detail with reference to the preferred embodiment, the present invention is not limited thereto. For example, various embodiments may be applied to the present invention. Thus, technical idea and scope of claims set forth below are not limited to the preferred embodiments.

According to the embodiment of the present invention, the native oxide formed on the substrate may be removed, and also, it may prevent the native oxide from being formed on the substrate. Thus, the epitaxial layer may be effectively formed on the substrate.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An equipment for manufacturing a semiconductor, the equipment comprising:
a cleaning chamber in which a cleaning process is performed on substrates;
an epitaxial chamber in which an epitaxial process for forming an epitaxial layer on each of the substrates is performed; and
a transfer chamber to which the cleaning chamber and the epitaxial chamber are connected to sides surfaces thereof, the transfer chamber comprising a substrate handler for transferring the substrates, on which the cleaning process is completed, into the epitaxial chamber,
wherein the cleaning chamber comprises:
a reaction chamber connected to a side surface of the transfer chamber to perform a reaction process on the substrates; and
a heating chamber connected to a side surface of the transfer chamber to perform a heating process on the substrates,
wherein the reaction chamber and the heating chamber are vertically stacked on each other.

2. The equipment of claim 1, wherein the transfer chamber comprises first and second transfer passages through which the substrates are entered into the cleaning chamber,
the reaction chamber comprises a reaction passage through which the substrates are entered,
the heating chamber comprises a heating passage through which the substrates are entered, and
the equipment further comprises a reaction-side gate valve for separating the reaction chamber from the transfer chamber and a heating-side gate valve for separating the heating chamber from the transfer chamber.

3. The equipment of claim 1, wherein the reaction chamber comprises:
a radical supply line connected to the reaction chamber to supply radicals; and
a gas supply line connected to the reaction chamber to supply a reaction gas.

4. The equipment of claim 3, wherein the reaction chamber further comprises a susceptor on which the substrates are placed, the susceptor rotating the substrates during the reaction process.

5. The equipment of claim 3, wherein the reaction gas comprises a fluoride gas comprising nitrogen fluoride (NF3).

6. The equipment of claim 1, wherein the heating chamber comprises:
a susceptor on which the substrates are placed; and
a heater heating the substrates placed on the susceptor.

7. The equipment of claim 1, further comprising a buffer chamber connected to a side surface of the transfer chamber, the buffer chamber comprising a storage space for stacking the substrates;
wherein the substrate handler successively stacks the substrates, on which the cleaning process is completed, into the storage space, transfers the stacked substrates into the epitaxial chamber, and successively stacks the substrates, on which the epitaxial layers are respectively formed, into the storage space.

8. The equipment of claim 7, wherein the storage space comprises a first storage space in which the substrates, on which the cleaning process is completed, are stored and a second storage space in which the substrates, on which the epitaxial layers are respectively formed, are stored.
